(19) United States
(12) Patent Application Publication
(10) Pub. No.: US 2026/0140518 A1
(43) Pub. Date: May 21, 2026

(54) AUTONOMOUS DRIVING PERFORMANCE EVALUATION DEVICE AND METHOD

(71) Applicants: HYUNDAI MOTOR COMPANY, Seoul (KR); Kia Corporation, Seoul (KR)

(72) Inventors: Woocheul LEE, Hwaseong-si (KR); Yong Ho NOH, Hwaseong-si (KR); Shuai CHENG, Shandong (CN)

(73) Assignees: HYUNDAI MOTOR COMPANY, Seoul (KR); Kia Corporation, Seoul (KR)

(21) Appl. No.: 18/966,011

(22) Filed: Dec. 2, 2024

(30) Foreign Application Priority Data
Nov. 15, 2024 (CN) 202411633616.2

(51) Int. Cl. G05D 1/86; G05D 109/10

(52) U.S. Cl. CPC G05D 1/86; G05D 2109/10

(57) ABSTRACT

An autonomous driving performance evaluation device includes a navigation providing unit configured to provide a virtual road navigation for evaluating autonomous driving performance when it is detected that a vehicle enters a driving test site, an evaluation mode setting unit configured to variably set an evaluation mode of the virtual road navigation according to a purpose of evaluating autonomous driving performance, and a scenario providing unit configured to selectively provide at least one scenario among a plurality of scenarios included in the virtual road navigation according to the set evaluation mode, wherein the virtual road navigation guides a virtual road virtually generated from a specific actual evaluation road designated for evaluating the autonomous driving performance.

### CROSS-REFERENCE TO RELATED APPLICATION

The present application claims priority to and the benefit of Chinese Patent Application No. 202411633616.2 filed in the Chinese National Intellectual Property Administration on Nov. 15, 2024, the entire contents of which is incorporated herein for all purposes by this reference.

### BACKGROUND OF THE PRESENT DISCLOSURE

### Field of the Present Disclosure

The present disclosure relates to an autonomous driving performance evaluation device and method, and more particularly, to an autonomous driving performance evaluation device and method using a virtual road.

### Description of Related Art

In relation to the development of navigation-linked autonomous driving highway driving assist (HDA) performance, there is a risk of driving a vehicle which is not secured in performance on actual highways. Evaluation of vehicle control operations linked to advanced driving assistance system (ADAS) while driving on actual highways is vulnerable to safety issues, raising the risk of occurrence of several accidents.

Furthermore, a lot of time and manpower are mobilized to find evaluation conditions, and running simulations using a database provided separately by a developer makes it difficult to check actual vehicle performance.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing an autonomous driving performance evaluation device and method configured for using virtual highways generated in a driving test site so that an autonomous driving performance evaluation, which was made only in an actual highway, may be made in the driving test site to minimize the time and input resources required for an autonomous driving performance evaluation test and increase the safety of evaluation.

The present disclosure also attempts to provide an autonomous driving performance evaluation device and method configured for making an evaluation of performance of an advanced driver assistance system (ADAS) linked to navigation of a connected car without space restrictions by virtualizing and multi-layering a navigation map provided to the connected car in real time and transmitting the same.

According to exemplary embodiments of the present disclosure, an autonomous driving performance evaluation device includes: a navigation providing unit configured to provide a virtual road navigation for evaluating autonomous driving performance in response that a vehicle enters a driving test site; an evaluation mode setting unit configured to variably set an evaluation mode of the virtual road navigation according to a purpose of evaluating the autonomous driving performance of the vehicle; and a scenario providing unit configured to selectively provide at least one scenario among a plurality of scenarios included in the virtual road navigation according to the set evaluation mode, wherein the virtual road navigation guides a virtual road virtually generated from a predetermined actual evaluation road designated for evaluating the autonomous driving performance.

The navigation providing unit may transmit the virtual road navigation from a navigation database (DB) to the vehicle when it is detected that the vehicle is provided with a navigation linked to the navigation DB.

The navigation DB may include autonomous driving performance information of the vehicle updated in real time online and virtual road navigation information for performance evaluation purposes.

The navigation providing unit may provide the virtual road navigation including a multi-layer including a plurality of layers each including at least one scenario.

Each evaluation mode may include at least one layer, and the evaluation mode setting unit is configured to select at least one layer among the multi-layers through variable settings of the evaluation mode.

The evaluation mode setting unit may be configured to determine the purpose of evaluating the autonomous driving performance based on autonomous driving performance information of the vehicle detected to have entered the driving test site and set an evaluation mode of the virtual road navigation based on the determined purpose.

The evaluation mode setting unit may set the evaluation mode corresponding to the purpose of evaluating the autonomous driving performance input by a user in real time through an interface provided in the vehicle.

The scenario providing unit may provide at least one predetermined scenario to correspond to the selected at least one layer, and the at least one scenario may include a speed camera response scenario, a section enforcement camera response scenario, a toll gate section response scenario, a tunnel section response scenario, and a sign response scenario.

The evaluation mode setting unit may set a predetermined evaluation mode for sequentially providing the plurality of layers in a predetermined order when the purpose of evaluating the autonomous driving performance meets a specific purpose including long-distance driving.

The evaluation mode setting unit may vary a layer and provides the varied layer every time a time point when the vehicle completes one lap of the driving test site is detected in the specific evaluation mode.

According to exemplary embodiments of the present disclosure, an autonomous driving performance evaluation method includes: providing a virtual road navigation for evaluating autonomous driving performance in response that a vehicle enters a driving test site; variably setting an evaluation mode of the virtual road navigation according to a purpose of evaluating the autonomous driving performance of the vehicle; and selectively providing at least one scenario among a plurality of scenarios included in the virtual road navigation according to the set evaluation mode, wherein the virtual road navigation guides a virtual road virtually generated from a predetermined actual evaluation road designated for evaluating the autonomous driving performance.

The providing of the virtual road navigation may further include transmitting the virtual road navigation from a navigation database (DB) to the vehicle when it is detected that the vehicle is provided with a navigation linked to the navigation DB.

The navigation DB may include autonomous driving performance information of the vehicle updated in real time online and virtual road navigation information for performance evaluation purposes.

The providing of the virtual road navigation may further include providing the virtual road navigation including a multi-layer including a plurality of layers each including at least one scenario.

Each evaluation mode may include at least one layer, and the setting of the evaluation mode of the virtual road navigation may further include selecting at least one layer among the multi-layers through variable settings of the evaluation mode.

The setting of the evaluation mode of the virtual road navigation may further include determining the purpose of evaluating the autonomous driving performance based on autonomous driving performance information of the vehicle detected to have entered the driving test site; and setting an evaluation mode of the virtual road navigation based on the determined purpose.

The setting of the evaluation mode of the virtual road navigation may further include setting the evaluation mode corresponding to the purpose of evaluating the autonomous driving performance input by a user in real time through an interface provided in the vehicle.

The selectively providing of the scenario may further include providing at least one predetermined scenario to correspond to the selected at least one layer based on the purpose of evaluating autonomous driving performance, and the at least one scenario may include a speed camera scenario, a section enforcement camera scenario, a toll gate section scenario, a tunnel section scenario, and a sign response scenario.

The setting of the evaluation mode of the virtual road navigation may further include setting a predetermined evaluation mode for sequentially providing the plurality of layers in a predetermined order when the purpose of evaluating the autonomous driving performance meets a specific purpose including long-distance driving.

The setting of the evaluation mode of the virtual road navigation may further include varying a layer and providing the varied layer every time a time point when the vehicle completes one lap of the driving test site is detected in the specific evaluation mode.

In the autonomous driving performance evaluation device and method according to an exemplary embodiment of the present disclosure, the time and input resources required for the autonomous driving performance evaluation test may be minimized and the safety of evaluation may be increased by use of a virtual highway generated in a driving test site to enable autonomous driving performance evaluation, which was made only in an actual highway, at the driving test site.

In the autonomous driving performance evaluation device and method according to an exemplary embodiment of the present disclosure, an evaluation of performance of an advanced driver assistance system (ADAS) linked with navigation of a connected car may be performed without space restrictions by virtualizing and multi-layering a navigation map provided in real time to the connected car and transmitting the same.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 schematically illustrates an autonomous driving performance evaluation system according to an exemplary embodiment of the present disclosure.

FIG. 2 illustrates a multi-layer of a virtual road navigation according to an exemplary embodiment of the present disclosure.

FIG. 3 is a block diagram of an autonomous driving performance evaluation device according to an exemplary embodiment of the present disclosure.

FIG. 4 is a flowchart of an autonomous driving performance evaluation method according to an exemplary embodiment of the present disclosure.

FIG. 5 and FIG. 6 illustrate a virtual road provided through a virtual road navigation according to an exemplary embodiment of the present disclosure.

FIG. 7 is a diagram illustrating a computing device according to an exemplary embodiment of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, the present disclosure will be described more fully hereinafter with reference to the accompanying drawings, in which exemplary embodiments of the present disclosure are shown. As those skilled in the art would realize, the described exemplary embodiments of the present disclosure may be modified in various different ways, all without departing from the spirit or scope of the present disclosure. Accordingly, the drawings and description are to be regarded as illustrative in nature and not restrictive. Like reference numerals designate like elements throughout the specification.

Throughout the specification and claims, unless explicitly described to the contrary, the word “comprise”, and variations, such as “comprises” or “comprising”, will be understood to imply the inclusion of stated elements but not the exclusion of any other elements. It will be understood that, although the terms first, second, etc. may be used herein to describe various elements, these elements should not be limited by these terms. These terms are only used to distinguish one element from another.

The terms “part” “unit”, “module” described in the specification refer to a unit configured for processing at least one function or operation described in the present specification and may be implemented by hardware or circuit, software, or a combination of a hardware or circuit and software.

Hereinafter, various exemplary embodiments of the present disclosure will be described with reference to the drawings.

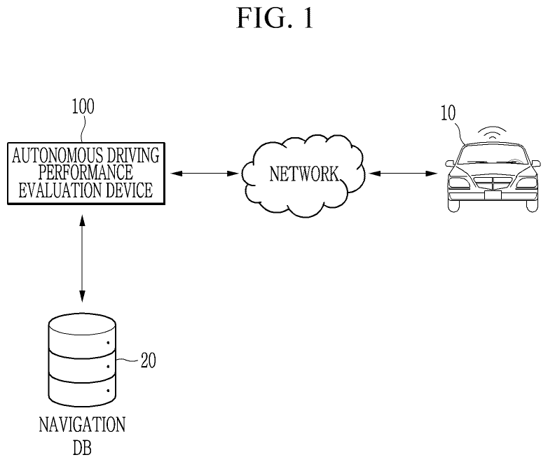

FIG. 1 schematically illustrates an autonomous driving performance evaluation system according to an exemplary embodiment of the present disclosure.

Referring to FIG. 1, the autonomous driving performance evaluation system includes an autonomous driving performance evaluation device 100, an autonomous vehicle 10, and a navigation database (DB) 20.

The autonomous vehicle 10 may correspond to a vehicle including autonomous driving functions including advance driving assistance system (ADAS) and navigation-linked autonomous driving functions (e.g., highway driving assistance (HAD) system).

The autonomous vehicle 10 may be a connected car vehicle provided with a navigation connected to the navigation DB 20. Hereinafter, the autonomous vehicle 10 may be referred to as a vehicle 10.

The autonomous driving performance evaluation device 100 generates a virtual highway at a driving test site and evaluates autonomous driving performance of the autonomous vehicle on the highway through a virtual road navigation provided for the generated virtual highway (virtual road).

The navigation DB 20 stores various information necessary for the autonomous driving performance evaluation device 100, including a virtual road navigation, a virtual road map, and scenario data that are updated in real time online.

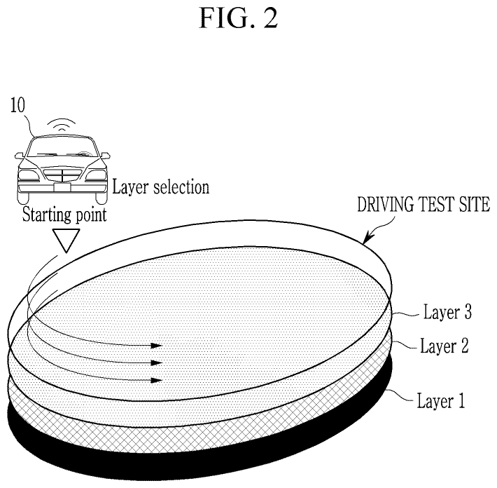

FIG. 2 illustrates a multi-layer of a virtual road navigation according to an exemplary embodiment of the present disclosure.

In FIG. 2, the vehicle 10 may output a virtual road navigation including a multi-layer structure obtained by virtualizing the driving test site provided from the autonomous driving performance evaluation device 100 (see FIG. 1) through an audio video navigation (AVN).

The vehicle 10 may provide an interface for setting an evaluation mode according to the purpose of evaluating autonomous driving performance.

The interface is a component configured for outputting electrical signals according to the on or off operations in the vehicle, through which the user can selectively manipulate the on or off operations in the vehicle, and may include, for example, an operating device such as a button or switch provided in the vehicle, an input device of an Audio, Video and Navigation (AVN) system, or a touchscreen.

A user may set the evaluation mode through an interface of the vehicle 10. Multiple evaluation modes may be provided. Each evaluation mode may include at least one assigned layer. Accordingly, when the user sets the evaluation mode, the corresponding layer may be selectively provided.

That is, the user may select a required layer in the multi-layer structure through the interface of the vehicle 10.

The evaluation mode may be automatically set as the vehicle 10 enters the driving test site. That is, the autonomous driving performance evaluation device 100 may detect autonomous driving performance information of the vehicle 10 from the vehicle 10 when it is determined that the vehicle 10 has entered the driving test site.

The autonomous driving performance evaluation device 100 may be configured to determine the purpose of evaluating the autonomous driving performance based on the detected autonomous driving performance information of the vehicle 10.

The autonomous driving performance evaluation device 100 may automatically set the evaluation mode of the virtual road navigation based on the determined purpose. That is, the autonomous driving performance evaluation device 100 may detect vehicle information including the autonomous driving performance information from the vehicle 10 and automatically determine the evaluation mode based the detected vehicle information.

Accordingly, the autonomous driving performance evaluation device 100 may automatically select and set at least one layer corresponding to the determined evaluation mode.

The driving test site is presented in a round shape, but it is not limited to this. The driving test site may be square, straight or oval in shape.

The autonomous driving performance evaluation device 100 provides a virtual road navigation to the vehicle 10 driving on the driving test site. In other words, the autonomous driving performance evaluation device 100 may guide a driver of the vehicle 10 that drives on the driving test site to a virtual road obtained by virtualizing a highway designated for driving performance evaluation through the virtual road navigation.

The virtual road navigation is provided in a multi-layer structure. The virtual road navigation including a multi-layer structure may provide different combinations of layers depending on the evaluation mode.

The autonomous driving performance evaluation device 100 provides the vehicle 10 with the virtual road navigation including at least one layer determined according to the evaluation mode.

By driving on the driving test site along the virtual road navigation provided through the autonomous driving performance evaluation device 100, the user may be provided with the same effect as driving on a designated highway for autonomous driving performance evaluation.

For example, Layer 1 may provide a virtual road navigation for evaluating the performance of a basic function of navigation-based smart cruise control (NSCC) of the vehicle 10. That is, at least one scenario for NSCC basic performance evaluation may be provided in Layer 1.

Layer 2 may provide a virtual road navigation for performance evaluation of a navigation-based smart cruise control-ramp (NSCC-R). In Layer 2, at least one scenario for NSCC-R performance evaluation may be optionally provided.

Layer 3 may provide a virtual road navigation for evaluating autonomous driving performance in areas where autonomous driving issues occur. In other words, Layer 3 provides a virtual road navigation that virtualizes a map of an area where the issue occurs, and scenario included in the map may be provided as it is on the virtual road.

The scenarios may include an enforcement camera response scenario, a section enforcement camera response scenario, an interchange (IC)/junction (JC)/toll gate section response scenario, and a tunnel section response scenario.

For example, the autonomous driving performance evaluation device 100 may provide a virtual road navigation including at least one layer selected from Layer 1 to Layer 3 according to an evaluation mode. Selected layers may be provided sequentially.

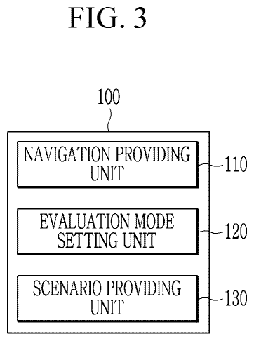

FIG. 3 is a block diagram of an autonomous driving performance evaluation device according to an exemplary embodiment of the present disclosure.

Referring to FIG. 3, the autonomous driving performance evaluation device 100 may include a navigation providing unit 110, an evaluation mode setting unit 120, and a scenario providing unit 130.

The navigation providing unit 110 may provide virtual road navigation for evaluating autonomous driving performance when it is detected that the vehicle enters the driving test site. The virtual road navigation may be a navigation that guides a virtual road which is virtually generated from a specific actual evaluation road designated for evaluating autonomous driving performance.

When it is detected that the vehicle is provided with a navigation linked to a navigation DB, the navigation providing unit 110 may transmit a virtual road navigation from the navigation DB to the vehicle.

The navigation DB 20 (see FIG. 1) may include autonomous driving performance information of the vehicle which is updated online in real time and virtual road navigation information for performance evaluation purposes.

The navigation providing unit 110 may provide the virtual road navigation including a multi-layer including a plurality of layers each including at least one scenario. In other words, the virtual road navigation may be implemented in a multi-layer structure. Each layer may provide navigation for different virtual roads.

The navigation providing unit 110 may provide the virtual road navigation included in a selected layer according to the evaluation mode set by the evaluation mode setting unit 120.

The evaluation mode setting unit 120 may variably set the evaluation mode of the virtual road navigation according to the purpose of evaluating autonomous driving performance.

Each evaluation mode may include at least one layer, and the evaluation mode setting unit may select at least one layer among the multi-layers through variable settings of the evaluation mode.

The evaluation mode setting unit 120 may be configured to determine the purpose of evaluating the autonomous driving performance based on autonomous driving performance information of the vehicle detected to have entered the driving test site.

The evaluation mode setting unit 120 may set the evaluation mode of the virtual road navigation based on the determined purpose of evaluating autonomous driving performance.

The evaluation mode setting unit 120 may set an evaluation mode corresponding to the purpose of evaluating the autonomous driving performance input by the user in real time through an interface provided in the vehicle.

That is, when the purpose of evaluating the autonomous driving performance is confirmed, the evaluation mode setting unit 120 may automatically set the corresponding evaluation mode.

If the purpose of evaluating the autonomous driving performance meets a specific purpose including long-distance driving, the evaluation mode setting unit 120 may set a specific evaluation mode that sequentially provides a plurality of layers in a certain order.

The evaluation mode setting unit 120 may change the provided layer whenever it is detected that the vehicle completes one lap of the driving test site in a specific evaluation mode.

For example, the evaluation mode setting unit 120 may sequentially vary the layers each time the vehicle passes a starting point.

The scenario providing unit 130 may selectively provide at least one scenario among the plurality of scenarios included in the virtual road navigation according to the set evaluation mode.

The scenario providing unit 130 may provide at least one predetermined scenario corresponding to the selected layer according to the evaluation mode.

At least one scenario may include a speed camera response scenario, a section enforcement camera response scenario, a toll gate section response scenario, a tunnel section response scenario, and a sign response scenario.

Speed Camera Response Scenario: The vehicle detects the speed camera, reduces speed to comply with the limit, and the autonomous driving performance evaluation device 100 tracks speed adjustments and potential violations, providing feedback.

Section Enforcement Camera Response Scenario: The vehicle maintains its average speed within a section to avoid speeding, and the autonomous driving performance evaluation device 100 calculates the average speed based on entry and exit times to assess compliance.

Toll Gate Section Response Scenario: The vehicle passes through an automated toll gate using RFID or license plate recognition for payment, and the autonomous driving performance evaluation device 100 monitors successful transactions and traffic flow.

Tunnel Section Response Scenario: The vehicle adheres to speed and lane rules inside the tunnel, while the autonomous driving performance evaluation device 100 continuously monitors speed, lane changes, and emergency responses.

Sign Response Scenario: The vehicle adjusts speed or changes lanes according to road signs, and the autonomous driving performance evaluation device 100 records the vehicle's response to the signs and evaluates for compliance.

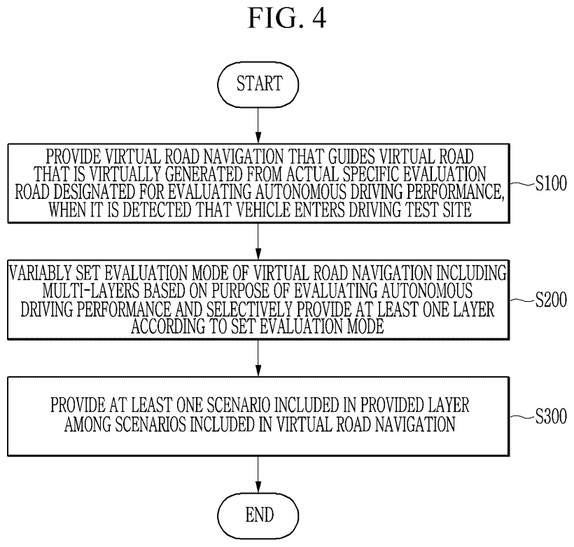

FIG. 4 is a flowchart of an autonomous driving performance evaluation method according to an exemplary embodiment of the present disclosure. The autonomous driving performance evaluation method of FIG. 4 may be performed through the autonomous driving performance evaluation device 100 (see FIG. 3).

In FIG. 4, when it is detected that the vehicle enters the driving test site, the autonomous driving performance evaluation device 100 may provide a virtual road navigation that guides a virtual road which is virtually generated from an actual specific evaluation road designated for evaluating autonomous driving performance (operation S100).

When it is detected that the vehicle is provided with a navigation linked to a navigation DB, the autonomous driving performance evaluation device 100 may transmit the virtual road navigation from the navigation DB to the vehicle.

The autonomous driving performance evaluation device 100 may variably set the evaluation mode of the virtual road navigation including multi-layers based on the purpose of evaluating the autonomous driving performance and selectively provide at least one layer according to the set evaluation mode (operation S200).

Each evaluation mode may include at least one layer. The autonomous driving performance evaluation device 100 may select and provide at least one layer among the multi-layers through variable setting of the evaluation mode.

A plurality of layers forming the multi-layer may each include at least one scenario.

The autonomous driving performance evaluation device 100 may be configured to determine the purpose of evaluating the autonomous driving performance based on autonomous driving performance information of the vehicle detected to have entered the driving test site.

The autonomous driving performance evaluation device 100 may set an evaluation mode for virtual road navigation based on the determined purpose.

Alternatively, the autonomous driving performance evaluation device 100 may set an evaluation mode to correspond to the purpose of evaluating the autonomous driving performance input by the user in real time through an interface provided in the vehicle.

The autonomous driving performance evaluation device 100 may provide at least one scenario included in the provided layer among the plurality of scenarios included in the virtual road navigation (operation S300).

The autonomous driving performance evaluation device 100 may provide at least one predetermined scenario to correspond to the selected layer based on the purpose of evaluating autonomous driving performance. The at least one scenario may include a speed camera response scenario, a section enforcement camera response scenario, a toll gate section response scenario, a tunnel section response scenario, and a sign response scenario.

If the purpose of evaluating the autonomous driving performance meets a specific purpose including long-distance driving, the autonomous driving performance evaluation device 100 may set a specific evaluation mode that sequentially provides a plurality of layers in a certain order.

The autonomous driving performance evaluation device 100 may variably provide a layer every time a time point when the vehicle completes one lap of the driving test site (for example, a time point when the vehicle passes the starting point) is detected in a specific evaluation mode.

For example, the autonomous driving performance evaluation device 100 may count the number of times the vehicle passes the starting point and continuously provide different layers according to the number information.

The autonomous driving performance evaluation device 100 may identify a plurality of layers in the multi-layer structure with parameters for each layer. When a vehicle entering the driving test site is detected, the autonomous driving performance evaluation device 100 may set an evaluation mode by determining the vehicle information and/or the purpose of evaluating the autonomous driving performance and call parameters designated for the set evaluation mode to select a layer.

The autonomous driving performance evaluation device 100 is configured to determine that the vehicle passes the starting point using Global Positioning System (GPS) information of the vehicle in the specific evaluation mode. The autonomous driving performance evaluation device 100 may check the turn every time the vehicle passes the starting point and sequentially transmit the layers while increasing the number.

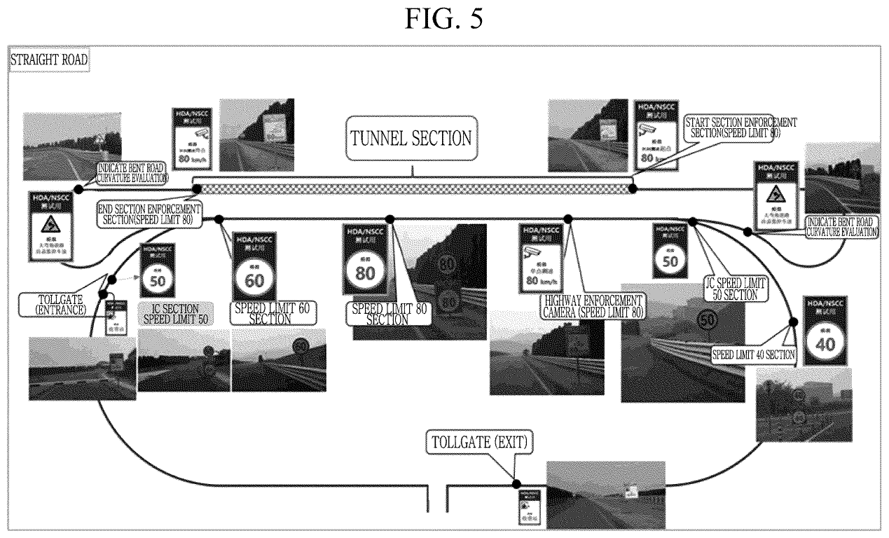

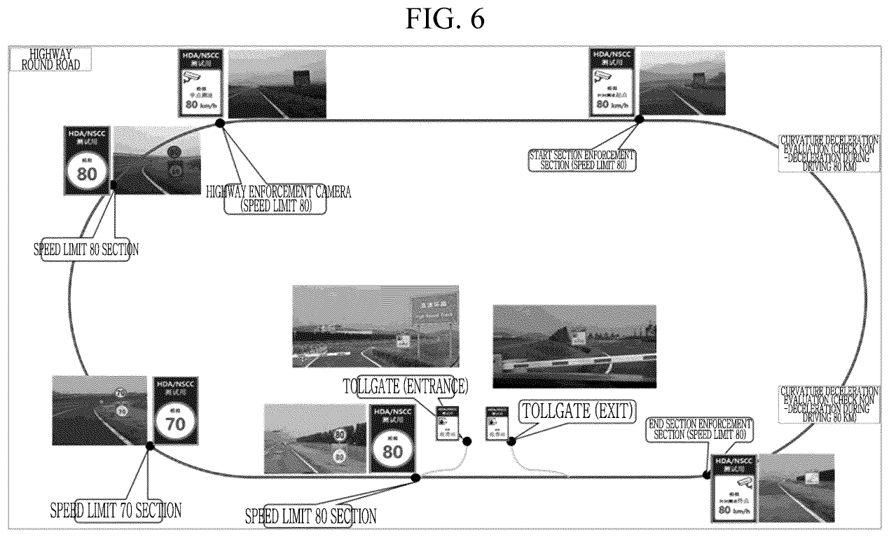

FIG. 5 and FIG. 6 illustrate a virtual road provided through a virtual road navigation according to an exemplary embodiment of the present disclosure.

FIG. 5 illustrates a virtual road navigation including various scenarios when a vehicle drives on a straight road (or straight section) in a highway.

FIG. 6 illustrates a virtual road navigation including various scenarios when a vehicle drives on a round road (or round section) in a highway.

In FIG. 5, the autonomous driving performance evaluation device 100 may provide a virtual road navigation for a straight road including a plurality of scenarios.

The straight road in FIG. 5 is obtained by virtualizing a highway designated for actual autonomous driving performance evaluation, and may be provided through a virtual road navigation. For example, the straight road in FIG. 5 may be provided as any one layer selected in a virtual road navigation of a multi-layer structure.

Referring to FIG. 5, the autonomous driving performance evaluation device 100 may provide a toll gate response scenario, a section enforcement response scenario, a tunnel section response scenario, and a speed limit section response scenario for evaluating autonomous driving performance through a layer that provides the virtual road navigation for a straight road in the highway.

In FIG. 6, the autonomous driving performance evaluation device 100 may provide virtual road navigation for a round road in a highway including a plurality of scenarios.

The round road in FIG. 6 is obtained by virtualizing a highway designated for actually evaluating autonomous driving performance, and may be provided through a virtual road navigation. For example, the round road of FIG. 6 may be provided by another layer selected from a virtual road navigation of a multi-layer structure.

Referring to FIG. 6, the autonomous driving performance evaluation device 100 may provide a toll gate section response scenario, a speed limit section response scenario, and an enforcement camera section response scenario, a curvature deceleration evaluation response scenario for evaluating autonomous driving performance.

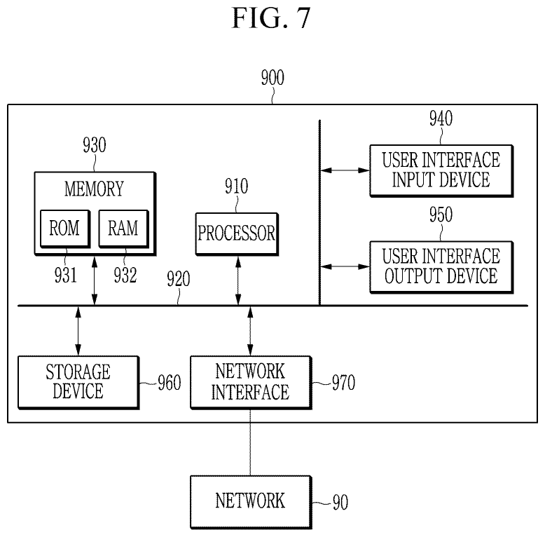

FIG. 7 is a diagram illustrating a computing device according to an exemplary embodiment of the present disclosure.

Referring to FIG. 7, an autonomous driving performance evaluation device and method according to exemplary embodiments of the present disclosure may be implemented using a computing device 900.

The computing device 900 may include at least one of a processor 910, a memory 930, a user interface input device 940, a user interface output device 950, and a storage device 560 that communicate with each other via a bus 920. The computing device 900 may also include a network interface 970 which is electrically connected to a network 90. The network interface 970 may transmit or receive signals to or from other entities through the network 90.

The processor 910 may be implemented in various types, such as a micro controller unit (MCU), an application processor (AP), a central processing unit (CPU), a graphics processing unit (GPU), a neural processing unit (NPU), etc and may be a semiconductor device that executes instructions stored in the memory 930 or the storage device 960. Processor 910 may be configured to implement the functions and methods described above with respect to FIGS. 1 to 6.

The memory 930 and storage device 960 may include various types of volatile or non-volatile storage mediums. For example, the memory may include read-only memory (ROM) 931 and random access memory (RAM) 932. In the exemplary embodiment of the present disclosure, the memory 930 may be located inside or outside the processor 910, and the memory 930 may be connected to the processor 910 through various known units.

In some exemplary embodiments of the present disclosure, at least some components or functions of the autonomous driving performance evaluation device and method according to the exemplary embodiments of the present disclosure may be implemented as a program or software running on the computing device 900, and the program or software may be stored in a computer-readable medium.

In some exemplary embodiments of the present disclosure, at least some components or functions of the autonomous driving performance evaluation device and method according to the exemplary embodiments of the present disclosure may be implemented using hardware or circuit of the computing device 900 or may be implemented as separate hardware or circuit which may be electrically connected to the computing device 900.

In the flowchart described with reference to the drawings, the flowchart may be performed by the controller or the processor. The order of operations in the flowchart may be changed, multiple operations may be merged, or any operation may be divided, and a specific operation may not be performed. Furthermore, the operations in the flowchart may be performed sequentially, but not necessarily performed sequentially. For example, the order of the operations may be changed, and at least two operations may be performed in parallel.

Hereinafter, the fact that pieces of hardware are coupled operably may include the fact that a direct and/or indirect connection between the pieces of hardware is established by wired and/or wirelessly.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described to explain certain principles of the present disclosure and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. An autonomous driving performance evaluation apparatus comprising:
a navigation providing unit configured to provide a virtual road navigation for evaluating autonomous driving performance of a vehicle in response that the vehicle enters a driving test site;
an evaluation mode setting unit configured to variably set an evaluation mode of the virtual road navigation according to a purpose of evaluating the autonomous driving performance of the vehicle; and
a scenario providing unit configured to selectively provide at least one scenario among a plurality of scenarios included in the virtual road navigation according to the set evaluation mode,
wherein the virtual road navigation guides a virtual road virtually generated from a predetermined actual evaluation road designated for evaluating the autonomous driving performance.

2. The autonomous driving performance evaluation apparatus of claim 1, wherein the navigation providing unit is configured to transmit the virtual road navigation from a navigation database (DB) to the vehicle in response that the vehicle is provided with a navigation linked to the navigation DB.

3. The autonomous driving performance evaluation apparatus of claim 2, wherein the navigation DB includes autonomous driving performance information of the vehicle updated in real time online and virtual road navigation information for performance evaluation purposes.

4. The autonomous driving performance evaluation apparatus of claim 1, wherein the navigation providing unit is configured to provide the virtual road navigation including a multi-layer including a plurality of layers each including at least one scenario.

5. The autonomous driving performance evaluation apparatus of claim 4, wherein each evaluation mode includes at least one layer, and the evaluation mode setting unit is configured to select at least one layer among the multi-layers through variable settings of the evaluation mode.

6. The autonomous driving performance evaluation apparatus of claim 5, wherein the evaluation mode setting unit is configured to determine the purpose of evaluating the autonomous driving performance based on autonomous driving performance information of the vehicle detected to have entered the driving test site and configured to set an evaluation mode of the virtual road navigation based on the determined purpose.

7. The autonomous driving performance evaluation apparatus of claim 5, wherein the evaluation mode setting unit is configured to set the evaluation mode corresponding to the purpose of evaluating the autonomous driving performance input by a user in real time through an interface provided in the vehicle.

8. The autonomous driving performance evaluation apparatus of claim 5,
wherein the scenario providing unit is configured to provide at least one predetermined scenario to correspond to the selected at least one layer, and
wherein the at least one scenario includes a speed camera response scenario, a section enforcement camera response scenario, a toll gate section response scenario, a tunnel section response scenario, and a sign response scenario.

9. The autonomous driving performance evaluation apparatus of claim 4, wherein the evaluation mode setting unit is configured to set a predetermined evaluation mode for sequentially providing the plurality of layers in a predetermined order in response that the purpose of evaluating autonomous driving performance meets a predetermined purpose including long-distance driving.

10. The autonomous driving performance evaluation apparatus of claim 9, wherein the evaluation mode setting unit varies a layer and provides the varied layer every time a time point when the vehicle completes one lap of the driving test site is detected in the predetermined evaluation mode.

11. An autonomous driving performance evaluation method comprising:
providing, by a processor, a virtual road navigation for evaluating autonomous driving performance of a vehicle in response that the vehicle enters a driving test site;
variably setting, by the processor, an evaluation mode of the virtual road navigation according to a purpose of evaluating the autonomous driving performance of the vehicle; and
selectively providing, by the processor, at least one scenario among a plurality of scenarios included in the virtual road navigation according to the set evaluation mode,
wherein the virtual road navigation guides a virtual road virtually generated from a predetermined actual evaluation road designated for evaluating the autonomous driving performance.

12. The autonomous driving performance evaluation method of claim 11, wherein the providing of the virtual road navigation further includes:
transmitting the virtual road navigation from a navigation database (DB) to the vehicle in response that the vehicle is provided with a navigation linked to the navigation DB.

13. The autonomous driving performance evaluation method of claim 12, wherein the navigation DB includes autonomous driving performance information of the vehicle updated in real time online and virtual road navigation information for performance evaluation purposes.

14. The autonomous driving performance evaluation method of claim 11, wherein the providing of the virtual road navigation further includes:
providing the virtual road navigation including a multi-layer including a plurality of layers each including at least one scenario.

15. The autonomous driving performance evaluation method of claim 14,
wherein each evaluation mode includes at least one layer, and
wherein the setting of the evaluation mode of the virtual road navigation further includes selecting at least one layer among the multi-layers through variable settings of the evaluation mode.

16. The autonomous driving performance evaluation method of claim 15, wherein the setting of the evaluation mode of the virtual road navigation further includes:
determining the purpose of evaluating the autonomous driving performance based on autonomous driving performance information of the vehicle detected to have entered the driving test site; and
setting an evaluation mode of the virtual road navigation based on the determined purpose.

17. The autonomous driving performance evaluation method of claim 15, wherein the setting of the evaluation mode of the virtual road navigation further includes:
setting the evaluation mode corresponding to the purpose of evaluating the autonomous driving performance input by a user in real time through an interface provided in the vehicle.

18. The autonomous driving performance evaluation method of claim 15, wherein the selectively providing of the scenario further includes:
providing at least one predetermined scenario to correspond to the selected at least one layer based on the purpose of evaluating autonomous driving performance, and
the at least one scenario includes a speed camera scenario, a section enforcement camera scenario, a toll gate section scenario, a tunnel section scenario, and a sign response scenario.

19. The autonomous driving performance evaluation method of claim 14, wherein the setting of the evaluation mode of the virtual road navigation further includes:
setting a predetermined evaluation mode for sequentially providing the plurality of layers in a predetermined order in response that the purpose of evaluating the autonomous driving performance meets a predetermined purpose including long-distance driving.

20. The autonomous driving performance evaluation method of claim 19, wherein the setting of the evaluation mode of the virtual road navigation further includes:
varying a layer and providing the varied layer every time a time point when the vehicle completes one lap of the driving test site is detected in the predetermined evaluation mode.
